(19) United States
(12) Patent Application Publication
(10) Pub. No.: US 2012/0103507 A1
(43) Pub. Date: May 3, 2012

(54) Photosensitive composite and build-up insulation film with the photosensitive composite, and method for manufacturing circuit board using the build-up insulation film

(75) Inventors: Jae Choon Cho, Suwon-si (KR); Hyung Mi Jung, Suwon-si (KR); Hwa Young Lee, Suwon-si (KR); Choon Keun Lee, Suwon-si (KR)

(73) Assignee: Samsung Electro-Mechanics Co., Ltd., Suwon (KR)

(21) Appl. No.: 13/137,937

(22) Filed: Sep. 21, 2011

(30) Foreign Application Priority Data
Nov. 2, 2010 (KR) 10-2010-0108176

(51) Int. Cl. B32B 38/04; G03F 7/09; B32B 37/14; H01L 21/02; B32B 37/02; G03F 7/028; G03F 7/38

(52) U.S. Cl. 156/253; 430/280.1; 430/271.1; 430/315; 430/314

(57) ABSTRACT

Disclosed herein is a method for manufacturing a circuit board. The method for manufacturing a circuit board includes: preparing a photosensitive composite; preparing a build-up insulating film by casting the photosensitive composite into a film made of poly ethylene terephthalate (PET) material; stacking the build-up insulation film on the board; forming via holes on the build-up insulation film by using a photolithography process; and forming conductive vias in the via holes.

### CROSS REFERENCE(S) TO RELATED APPLICATIONS

This application claims the benefit under 35 U.S.C. Section [120, 119, 119(e)] of Korean Patent Application Serial No. 10-2010-0108176, entitled “Photosensitive Composite And Build-Up Insulation Film With The Photosensitive Composite, And Method for Manufacturing Circuit Board Using the Build-up Insulation Film” filed on Nov. 2, 2010, which is hereby incorporated by reference in its entirety into this application.

### BACKGROUND OF THE INVENTION

1. Technical Field

The present invention relates to a build-up insulation film for manufacturing a build-up multi layer circuit board, and more particularly, to a photosensitive composite for forming via holes using a photo lithography process and a build-up insulation film with the photosensitive composite and a method for manufacturing a circuit board using the build-up insulation film.

2. Description of the Related Art

A build-up multi layer printed circuit board (PCB) in a general printed circuit board (PCB) is manufactured by forming a laminate, in which build-up insulation films, or the like, in a thin plate type are stacked, and performing a firing process, or the like, on the laminate. During these processes, the laminate is provided with conductive vias for conducting circuit patterns formed in different insulating layers within the laminate. In order to form the conductive vias, a via hole forming process in the film laminate is added. At present, a method of using a laser machining process irradiating laser to the film laminate has been prevalently used in order to form the via holes.

However, when the via holes are formed using the above-mentioned laser, process cost for forming the via holes are increased, which is the main factor for increasing the manufacturing costs of the circuit board. Further, the via hole formed by the laser machining process creates a shape in which a width thereof is narrow toward the inner side of the via hole. Therefore, the upper width and lower width of the via holes are different from each other, such that the upper width and lower width of the conductive vias formed in the via holes are also different from each other. This causes a limitation in designing the printed circuit board that is being highly integrated, while increasing the electric resistance of the conductive via.

### SUMMARY OF THE INVENTION

An object of the present invention is to provide a photosensitive composite capable of improving a manufacturing process efficiency of a printed circuit board and build-up insulation film with the same.

Another object of the present invention is to provide a photosensitive composite capable of forming via holes using a photo lithography process and a build-up insulation film with the same.

Another object of the present invention is to provide a method for manufacturing a circuit board capable of improving a manufacturing process.

According to an exemplary embodiment of the present invention, there is provided a photosensitive composite for manufacturing a circuit board, including: a composite epoxy resin; additives added to the composite epoxy resin; and a photosensitive material providing photosensitivity to the composite epoxy resin, wherein the photosensitive material includes: a photo initiator; and a photosensitive monomer having double coupling and carboxylic acid (COOH).

The photosensitive monomer may have a chemical structure using a bisphenol-A type epoxy resin structure as a backbone to perform free-radical polymerization.

The composite epoxy resin may include bisphenol-A type epoxy resin, cresol novolac epoxy resin, rubber modified epoxy resin, and phosphorus-based epoxy resin.

The additives may include at least any one of a hardener, a hardening accelerator, a flame retardant supplement, and a filler.

According to an exemplary embodiment of the present invention, there is provided a build-up insulation film for manufacturing a circuit board, including: a film made of poly ethylene terephthalate (PET) material; and an insulation film made of a photosensitive composite cast into the film and including composite epoxy resin, additives, photo initiator, and photosensitive monomer having double coupling and carboxylic acid (COOH).

The photosensitive monomer may have a chemical structure using a bisphenol-A type epoxy resin structure as a backbone to perform free-radical polymerization.

According to another exemplary embodiment of the present invention, there is provided a method for manufacturing a circuit board, including: preparing a photosensitive composite; preparing a build-up insulating film by casting the photosensitive composite into a film made of poly ethylene terephthalate (PET) material; stacking the build-up insulation film on the board; forming via holes on the build-up insulation film by using a photolithography process; and forming conductive vias in the via holes.

The preparing the photosensitive composite may include: preparing composite epoxy resin; adding at least any one of a hardener, a hardening accelerator, a flame retardant supplement, and a filler to the composite epoxy resin; and mixing a photo initiator and a photosensitive monomer having double coupling and carboxylic acid (COOH) with the composite epoxy resin.

The photosensitive monomer may have a chemical structure using a bisphenol-A type epoxy resin structure as a backbone to perform free-radical polymerization.

The forming the via hole may include: performing an exposure process selectively irradiating light in a via forming area of the build-up insulation film; and performing a developing process selectively removing an area other than the via forming area by using a developing solution having etching selectivity for an area other than the via forming area.

The forming the via hole may further include performing a precure process heat-treating the build-up insulation film prior to the performing the developing process.

The forming the conductive via may include: forming surface roughness for the build-up insulation film formed with the via hole; and performing a plating process forming a plating film that conformally covers the build-up insulation film.

The forming the conductive via may include performing a precure process heat-treating the build-up insulation film prior to the forming the surface roughness.

### BRIEF DESCRIPTION OF THE DRAWINGS

FIG. 1 is a diagram showing a photo initiator of a photosensitive composite according to an exemplary embodiment of the present invention;

FIG. 2 is a flow chart showing a method of manufacturing a circuit board according to an exemplary embodiment of the present invention; and

FIGS. 3 to 7 are drawings for explaining a method for manufacturing a circuit board according to the exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a photosensitive composite, a build-up insulation film with the photosensitive composite, and a method for manufacturing a circuit board using the build-up insulation film will be described with reference to the accompanying drawings.

Photosensitive Composite

A photosensitive composite according to an exemplary embodiment of the present invention may be a composite for manufacturing an insulation film forming an interlayer insulating layer of a build-up multi layer circuit board. As an example, the photosensitive composite may include epoxy resin, additives, and a photosensitive material.

The epoxy resin may include at least any one of bisphenol-A type epoxy resin, cresol novolac epoxy resin, rubber modified epoxy resin, and phosphorus-based epoxy resin. An example of the epoxy resin may include composite epoxy resin made of the bisphenol-A type epoxy resin, the cresol novolac epoxy resin, the rubber modified epoxy resin, and the phosphorus-based epoxy resin.

An average resin equivalent of the bisphenol-A type epoxy resin may be controlled to be 100 to 700. When the average resin equivalent is below 100, it is difficult to obtain material characteristics required for the photosensitive composite. On the other hand, when the average resin equivalent exceeds 700, it is difficult to melt the epoxy resin in a solvent and the melting point is too high, such that the simplified manufacturing of the build-up insulation film to be manufactured may be degraded. In addition, the bisphenol-A type epoxy resin may be controlled to have 1 to 20 parts by weight in the composite epoxy resin. When the content of the bisphenol-A type epoxy resin is below 1 part by weight, an adhesion with metal wirings formed on the insulation film when additionally manufacturing the circuit board may be degraded. On the other hand, when the content of the bisphenol-A type epoxy resin exceeds 20 parts by weight, the thermal and electrical characteristics and moisture resistance of the photosensitive composite may be degraded.

The cresol novolac epoxy resin has characteristics capable of obtaining a cured product having high heat resistance, thereby making it possible improving the thermal stability of the circuit board to be manufactured. An average resin equivalent of the cresol novolac epoxy resin may be controlled to be 100 to 600. When the average resin equivalent of the cresol novolac epoxy resin is below 100, it may be difficult to obtain physical properties required for the photosensitive composite. On the other hand, when the average resin equivalent of the cresol novolac epoxy resin exceeds 600, it is difficult to melt the composite epoxy resin in a solvent and the melting point is too high, such that the manufacturing easiness of the build-up insulation film may be degraded. In addition, the cresol novolac epoxy resin may be controlled to have 30 to 70 parts by weight in the composite epoxy resin. When the content of the cresol novolac epoxy resin is below 30 parts by weight in the composite epoxy resin, it is impossible to obtain the thermal and mechanical physical properties required for the insulation film and when it exceeds 70 parts by weight, the finally cured product may be brittle and the impact resistance may be lowered.

An average resin equivalent of the rubber modified epoxy resin may be controlled to be 100 to 500. When the average resin equivalent of the rubber modified epoxy resin is below 100, it is impossible to obtain physical properties required from the insulation material and when it exceeds 500, it is difficult to melt the epoxy resin in a solvent and the melting point is too high, such that the manufacturing easiness of the build-up insulation film may be degraded. In addition, the rubber modified epoxy resin may be controlled to have 1 to 20 parts by weight in the composite epoxy resin. When the content of the rubber modified epoxy resin is below 1 part by weight, it is impossible to obtain physical properties required for the build-up insulation film and when it exceeds 20 parts by weight, the finally cured product may be brittle, such that the possibility of cracks occurring may be increased and the impact resistance may be lowered.

The phosphorous-based epoxy resin may have excellent flame retardancy and self-extinguishing property. Therefore, the phosphorus-based epoxy resin may be added in order to implement a flame retardant circuit board. An average resin equivalent of the phosphorous-based epoxy resin may be controlled to 400 to 800. When the average resin equivalent of the phosphorous-based epoxy resin is below 400, it is impossible to obtain physical properties required from the photosensitive composite and when it exceeds 800, it is difficult to melt the epoxy resin in a solvent and the melting point is too high, such that the simplified manufacturing of the build-up insulation film using the photosensitive composite may be degraded. In addition, the phosphorous-based epoxy resin may be controlled to have 1 to 30 parts by weight in the composite epoxy resin. When the content of the phosphorus-based epoxy resin is below 1 part by weight, it is impossible to obtain flame retardancy required for the build-up insulation film and when it exceeds 30 parts by weight, the electrical and mechanical physical properties of the build-up insulation film may be degraded.

The additives may include at least any one of a hardener, a hardening accelerator, a flame retardant supplement, and a filler. The hardener may include at least any one of phenol novolac and bisphenol novolac. An example of the hardener may include the bisphenol-A type (BPA) novolac epoxy resin hardener. In this case, the hardener may be controlled to have a softening point of 100 to 140° C. and a hydroxyl equivalent of 100 to 150.

The hardener may be mixed at an equivalent ratio of 0.5 to 1.3 for an epoxy group mixing equivalent of the composite epoxy resin. When the hardener is mixed at the equivalent ratio in the above-mentioned range, the hardening degree of the circuit board to be manufactured can be easily controlled during the process of manufacturing a board and the coefficient of thermal expansion of the circuit board may be reduced. When the equivalent ratio of the hardener is below 0.5, the thermal and mechanical properties of the composite resin composite is degraded and when it exceeds 1.3, an adhesion is degraded and the non-reaction hardener may occur.

As the hardening accelerator, the imidazole-based hardening accelerator may be used. For example, as the hardening accelerator, at least any one of 2-ethyl-4-methyl imidazole, 1-(2-cyanoethyl)-2-alkyl imidazole, and 2-phenyl imidazole may be used. The hardening accelerator may be controlled to have about 0.1 to 2 parts by weight in the composite resin composite. When the content of the hardening accelerator is below 0.1 parts by weight, the hardening speed is remarkably degraded, such that non-hardening may occur. On the other than, when the content of the hardening accelerator exceeds 2 parts by weight, it is difficult to control the hardening speed and thus, it is difficult to secure reproducibility during the manufacturing process.

The flame retardant supplement may be used to lower the content of the relatively expensive flame retardant epoxy resin. As the flame retardant supplement, a compound such as Al203 containing phosphorous may be used.

The filler may be provided to improve the mechanical, electrical, and thermal characteristics of the build-up insulation film. An example of the filler may include at least any one of graphite, carbon black, silica, and clay. Another example of the filler may include a calcium carbonate (CaCO3) filler. When the filler is a calcium carbonate-based inorganic filler, the surface may be treated by a silane coupling agent in order to improve the chemical coupling affinity with the composite epoxy resin. An example of the silane coupling agent may include aminos, epoxys, acryls, and vinyls, or the like. Another example of the filler may include a laminar silicate, talc, and ceramic powder, or the like. In addition, an example of the filler may include a metal oxide powder including at least any one of aluminum, magnesium, zinc, calcium, strontium, zirconium, barium, tin, neodymium, bismuth, lithium, samarium, and tantalum.

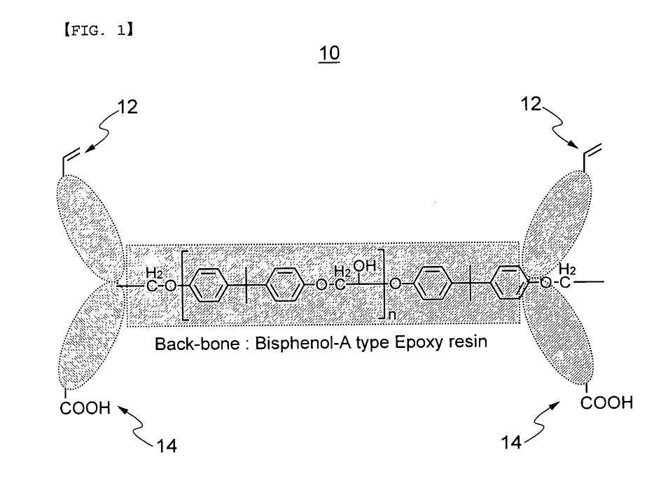

An example of the photosensitive material may include the photosensitive monomer and the photo initiator. An example of the photosensitive monomer may include a material having double coupling and carboxylic acid within a chemical structure. As shown in FIG. 1, an example of the photosensitive monomer 10 may include a material having a double coupling 12 and a carboxylic acid group 14 (COOH) as bisphenol-A type epoxy resin as a backbone but can perform free-radical polymerization. An example of the photosensitive monomer may include acrylate resin. As described above, the photosensitive composite can perform the polymerization reaction using light having a specific wavelength due to the photosensitive material.

As describe above, since the photosensitive composite includes the composite epoxy resin, the additives, the photo initiator, and the photo monomer capable of performing the free-radical polymerization reaction, it includes the photosensitive material capable of performing the polymerization reaction using light having a specific wavelength in the composite epoxy resin used as the interlayer insulting material of the circuit board, such that it may be used as a material for manufacturing a build-up insulation film capable of forming the via holes by using the photo lithography process.

Preparing Photosensitive Composite

250 g of bisphenol-A type epoxy resin, 1375 g of cresol novolac epoxy resin, 250 g of rubber modified epoxy resin, 625 g of phosphorus-based flame retardant epoxy resin, and 1636.06 g of 66.7 wt % (solvent: 2-methoxy ethanol) bisphenol-A (BPA) novolac resin hardener were added and then agitated in the mixing solvent of 316.54 g of methyl ethyl ketone (MEK) and 524 g of 2-methoxy ethanol at 300 rpm at normal temperature. Then, 735.56 g of inorganic filler was added and then, agitated at 400 rpm for 3 hours. Finally, 0.5 phr (part per hundred resin) of 2-ethyl-methyl imidazole was added and then, agitated for 30 minutes, such that the composite epoxy resin was prepared.

The phenol-based hardener, the photosensitive monomer having double coupling, the photosensitive initiator, and the inorganic filler, or the like, were added to the composite epoxy resin and then, the mixture was prepared by using a mixer. In this case, the content of the photosensitive monomer was controlled to have about 30 wt % with respect to the content of the phenol-based hardener. Further, the content of the inorganic filler was controlled to have approximately 17 wt % in the mixture. The inorganic filler was dispersed in the mixture by using a 3-Roll mill. Thereafter, the dispersed mixture was defoamed by using a defoaming device. Therefore, the photosensitive composite was prepared.

Preparing Build-Up Insulation Film

The defoamed photosensitive composite was cast into the film made of a material poly ethylene terephthalate (PET). The thickness of poly ethylene terephthalate may be controlled to be approximately 55 μm. Therefore, the build-up insulation film for manufacturing the build-up multi layer circuit board was manufactured.

The build-up insulation film having the above-mentioned structure may include the film made of a poly ethylene terephthalate (PET) material and the insulation film made of the photosensitive composite cast into the film and including the composite epoxy resin, the additives, the photo initiator, and the photo monomer capable of performing the free-radical polymerization reaction. Therefore, the build-up insulation film according to the present invention may form the via holes in which the conductive vias for interlayer conduction of the build-up multi layer printed circuit board are disposed by using the photo lithography process.

Manufacturing Circuit Board

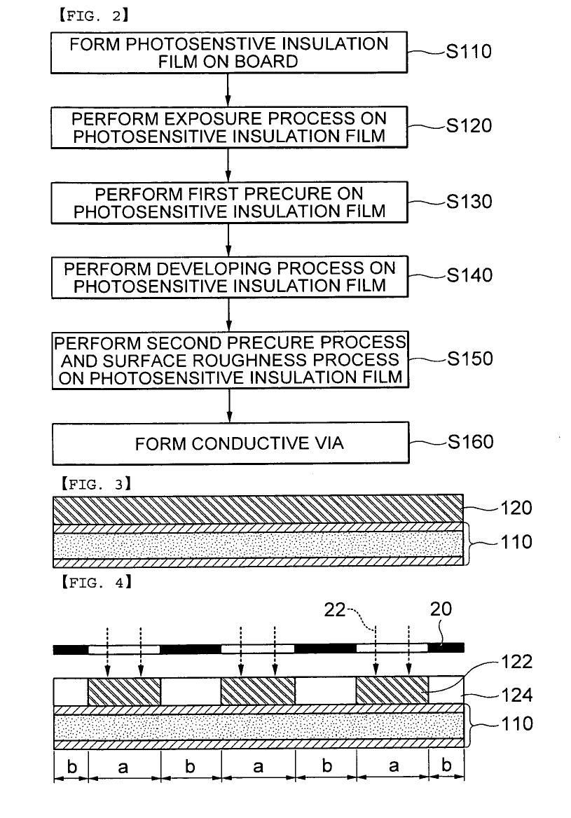

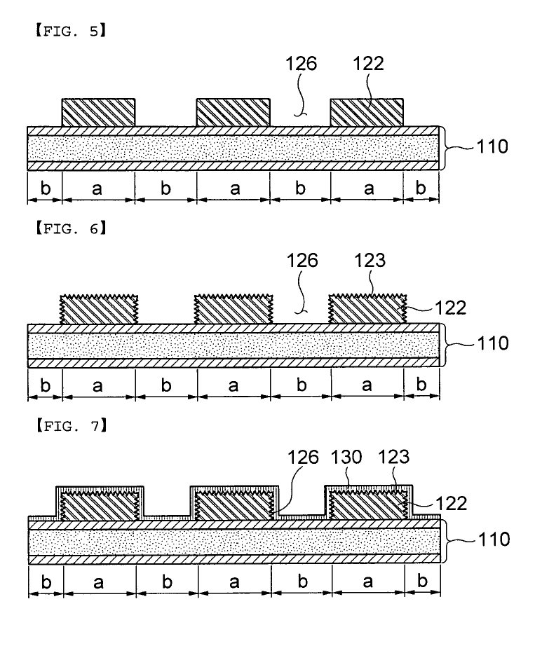

FIG. 2 is a flow chart showing a method of manufacturing a circuit board according to an exemplary embodiment of the present invention, and FIGS. 3 to 7 are diagrams for explaining a manufacturing process of a circuit board according to an exemplary embodiment of the present invention.

Referring to FIGS. 2 and 3, a photosensitive insulation film 120 may be formed on a board 110 (S110). For example, the board 110 may be prepared. The board 110 may be an inner layer circuit board for manufacturing the build-up multi layer circuit board. As one example, the board 110 may include a copper clad laminate (CCL). After the above-mentioned manufactured build-up insulation film is laminated on the board 110, the poly ethylene terephthalate (PET) of the build-up insulation film was removed. Therefore, the photosensitive insulation film 120 may be formed on the board 110 at a uniform thickness.

Referring to FIGS. 2 and 4, the photosensitive insulation film 120 may be subjected to the exposure process (S120). For example, after a predetermined mask 20 was prepared, then light 22 was selectively irradiated to an area (hereinafter, referred to as a first area: a) other than an area in which the vias of the photosensitive insulation film 120 are formed by the mask 20. The photo initiating reaction occurs in the photosensitive insulation film 122 (hereinafter, a first portion) on the first area ‘a’ to which the light 22 is irradiated, such that the photosensitive monomer may be formed into high polymer. That is, the first portion 122 may be formed into high polymer so that the photosensitive monomer performs the free-radical polymerization reaction. On the other hand, in the photosensitive insulation film portion (hereinafter, referred to as a second portion: 124) on the remaining area (hereinafter, referred to as a second area: b) to which the light 22 is not irradiated, the photosensitive monomer may maintain the monomer state as it is. The second area b may be an area in which the conductive vias may be additionally formed.

A first precure process may be performed on the photosensitive insulation film 120 (S130). The first precure process may be performed by heat-treating the photosensitive insulating film 120. The heat-treatment may be performed at a temperature atmosphere of approximately 60° C. for 2 hours. The thermosetting epoxy monomers within the photosensitive insulation film 120 may form a network by the first precure process. Therefore, the first portion 122 may be a state in which a proper amount of network is mixed by polymerizing the photosensitive monomer and hardening the high polymerized photosensitive high polymer and the thermosetting epoxy monomers. On the other hand, the second portion 124 may be a state in which a proper amount of network is mixed by hardening the photosensitive monomer and the thermosetting epoxy monomers.

Referring to FIGS. 2 and 5, the photosensitive insulating film 120 may be subjected to the developing process (S140). The process of performing the developing process may be made by supplying a developing solution that selectivity etches the second portion 124 of the photosensitive insulation film 120 on the board 110. To this end, the board 110 is dipped in the tank in which the developing solution is filled or the developing solution may be dispersed to the board 110. Various types of good solvents may be used as the developing solution. The second portion 124 may be selectively removed by the developing solution. Therefore, the first portion 122 having a via hole 126 selectively exposing the second area b may be formed on the board 110. In this case, the via hole 126 is formed by performing the photolithography process, such that the via hole 126 may have the same column shape having approximately same upper width and lower width.

Referring to FIGS. 2 and 6, a second precure process and a surface roughness forming process may be performed on the photosensitive insulation film 120 (S150). The second precure process may include the process of heat-treating the first portion (122 of FIG. 5). The heat-treatment may be performed at a temperature atmosphere of approximately 130° C. for 30 minutes. The surface roughness forming process may be a process of forming a surface roughness 123 on the surface of the first portion 122. The surface roughness 123 may be performed in order to improve the efficiency of forming the plating film during the plating process that is a subsequent process.

Referring to FIGS. 2 and 7, the conductive vias may be formed (S160). The conductive via forming process may be made by performing the plating process on the board 110. Therefore, the plating film 130 conformally covers the first portion 122 and the area for forming vias exposed by the first portion 122, that is, the second area b may be formed on the board 110. The plating film 130 may be a metal film including copper. Subsequently, the space in the second area b is filled with a filling material (not shown), thereby making it possible to form the conductive via in the via hole 126.

As described above, the method for manufacturing the circuit board according to the exemplary embodiment of the present invention attaches the build-up insulation film manufactured by using the photosensitive composite to the board (inner layer board) and then forming the via hole 126 in the build-up insulation film by using the photolithography process, thereby making it possible to form the conductive via in the via hole 126. In this case, the via hole 126 may have a column shape with approximately the same upper width and lower width. Therefore, the method for manufacturing the circuit board according to the present invention may manufacture the circuit board having the conductive vias having a column shape of which the upper width and the lower width are the same.

As set forth above, the photosensitive composite according to the present invention includes a composite epoxy resin, additives, a photo initiator, and a photo monomer capable of performing free-radical polymerization and thus, may be used as a material for manufacturing the build-up insulation film capable of forming the via holes by using the photolithography process.

The build-up insulation film according to the present invention may include the film made of a poly ethylene terephthalate (PET) material and the insulation film made of the photosensitive composite cast into the film and including the composite epoxy resin, the additives, the photo initiator, and the photo monomer capable of performing the free-radical polymerization reaction. Therefore, the build-up insulation film according to the present invention may be used as the build-up insulation film for manufacturing the circuit board capable of forming the via holes by using the photo lithography process since the holes may be formed in the desired areas of the insulation film through the exposure and developing processes.

The method for manufacturing a circuit board according to the present invention forms the via holes by using the photo lithography process, thereby making it possible to manufacture the circuit board including the conductive vias having the column shape of which upper width and lower width are the same, while reducing the manufacturing cost of the circuit board, as compared to forming the via holes using a laser of the related art.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A photosensitive composite for manufacturing a circuit board, comprising:
a composite epoxy resin;
additives added to the composite epoxy resin; and
a photosensitive material providing photosensitivity to the composite epoxy resin,
wherein the photosensitive material includes:
a photo initiator; and
a photosensitive monomer having double coupling and carboxylic acid (COOH).

2. The photosensitive composite for manufacturing a circuit board according to claim 1, wherein the photosensitive monomer has a chemical structure using a bisphenol-A type epoxy resin structure as a backbone to perform free-radical polymerization.

3. The photosensitive composite for manufacturing a circuit board according to claim 1, wherein the composite epoxy resin includes bisphenol-A type epoxy resin, cresol novolac epoxy resin, rubber modified epoxy resin, and phosphorus-based epoxy resin.

4. The photosensitive composite for manufacturing a circuit board according to claim 1, wherein the additives include at least any one of a hardener, a hardening accelerator, a flame retardant supplement, and a filler

5. A build-up insulation film for manufacturing a circuit board, comprising:
a film made of poly ethylene terephthalate (PET) material; and
an insulation film made of a photosensitive composite cast into the film and including composite epoxy resin, additives, photo initiator, and photosensitive monomer having double coupling and carboxylic acid (COOH).

6. The build-up insulation film for manufacturing a circuit board according to claim 5, wherein the photosensitive monomer has a chemical structure using a bisphenol-A type epoxy resin structure as a backbone to perform free-radical polymerization.

7. A method for manufacturing a circuit board, comprising:
preparing a photosensitive composite;
preparing a build-up insulating film by casting the photosensitive composite into a film made of poly ethylene terephthalate (PET) material;
stacking the build-up insulation film on the board;
forming via holes on the build-up insulation film by using a photolithography process; and
forming conductive vias in the via holes.

8. The method for manufacturing a circuit board according to claim 7, wherein the preparing the photosensitive composite includes:
preparing composite epoxy resin;
adding at least any one of a hardener, a hardening accelerator, a flame retardant supplement, and a filler to the composite epoxy resin; and
mixing a photo initiator and a photosensitive monomer having double coupling and carboxylic acid (COOH) with the composite epoxy resin.

9. The method for manufacturing a circuit board according to claim 8, wherein the photosensitive monomer has a chemical structure using a bisphenol-A type epoxy resin structure as a backbone to perform free-radical polymerization.

10. The method for manufacturing a circuit board according to claim 7, wherein the forming the via hole includes:
performing an exposure process selectively irradiating light in a via forming area of the build-up insulation film; and
performing a developing process selectively removing an area other than the via forming area by using a developing solution having etching selectivity for an area other than the via forming area.

11. The method for manufacturing a circuit board according to claim 10, wherein the forming the via hole further includes performing a precure process heat-treating the build-up insulation film prior to the performing the developing process.

12. The method for manufacturing a circuit board according to claim 7, wherein the forming the conductive via includes:
forming surface roughness for the build-up insulation film formed with the via hole; and
performing a plating process forming a plating film that conformally covers the build-up insulation film.

13. The method for manufacturing a circuit board according to claim 12, wherein the forming the conductive via includes performing a precure process heat-treating the build-up insulation film prior to the forming the surface roughness.
